(19) United States
(12) Patent Application Publication
(10) Pub. No.: US 2026/0173402 A1
(43) Pub. Date: Jun. 18, 2026

(54) MAGNETIC MEMORY CELL

(71) Applicant: IMEC VZW, Leuven (BE)

(72) Inventors: Florin Ciubotaru, Leuven (BE); Hanns Christoph Adelmann, Wilsele (BE)

(21) Appl. No.: 19/419,710

(22) Filed: Dec. 15, 2025

(30) Foreign Application Priority Data
Dec. 16, 2024 (EP) 24220148.1

(51) Int. Cl. H10B 61/00; G11C 11/16; G11C 11/56

(52) U.S. Cl. CPC H10B 61/20; G11C 11/161; G11C 11/1675; G11C 11/5607

(57) ABSTRACT

In one aspect, a magnetic memory cell is provided. The magnetic memory cell includes a magnetic memory element with at least one magnetic layer configured to store information in distinct magnetization states. The magnetic layer generates a stray magnetic field corresponding to its magnetization state. A magnetic field detection device is positioned in proximity to the magnetic memory element to detect variations in the stray magnetic field. The detection device includes a magnetostrictive and piezoelectric or a piezomagnetic and piezoelectric layer assembly. The magnetostrictive or piezomagnetic layer undergoes mechanical deformation in response to stray field changes, while the piezoelectric layer generates an electrical signal representing the stored information. A writing mechanism is configured to alter the magnetization state of the magnetic layer, enabling reliable data storage and retrieval.

### CROSS-REFERENCE TO RELATED APPLICATIONS

This application claims foreign priority to European Patent Application No. EP 24220148.1, filed Dec. 16, 2024, the content of which is incorporated by reference herein in its entirety.

### BACKGROUND

### Field

The disclosed technology relates generally to the field of magnetic memory technologies. More specifically, it relates to a memory reading mechanism configured to read information stored in magnetic memory cells.

### Description of the Related Technology

Magnetoresistive random access memory (MRAM) is a type of non-volatile memory that stores information in the magnetization state of a magnetic free layer within a magnetic tunnel junction (MTJ) stack. In an MRAM device, the writing process relies on a phenomenon known as the spin-transfer torque (STT) effect. A direct current (DC) flowing through the MTJ stack becomes spin-polarized as it passes through a fixed magnetic layer. This spin-polarized current exerts a torque on the magnetization of the free magnetic layer, causing it to switch between magnetization states depending on the polarization direction.

The magnetization states of the free and fixed magnetic layers can be aligned in parallel or anti-parallel configurations. These configurations correspond to two distinct resistance states of the MTJ, a low-resistance state and a high-resistance state, which define the binary memory states “0” and “1.” The memory is read by determining the resistance state of the MTJ, typically using a tunneling magnetoresistance (TMR) effect.

While MRAM offers advantages such as non-volatility, speed, and endurance, the physical mechanism underlying its operation imposes certain limitations. Specifically, the reliance on the TMR effect and the binary nature of the resistance states restrict MRAM to storing only one bit of information per MTJ. This constraint has driven research into alternative architectures and methods to increase storage density and functionality within individual memory cells.

### SUMMARY OF CERTAIN INVENTIVE ASPECTS

It is an object of embodiments of the disclosed technology to provide a magnetic memory cell comprising a good mechanism configured to read information stored in the magnetic memory cell and to provide a method of operating such a memory cell.

The above objective can be accomplished by a method and device according to the disclosed technology.

In a first aspect, embodiments of the disclosed technology relate to a magnetic memory cell. The magnetic memory cell can include a magnetic memory element with at least one magnetic layer. The magnetic layer can be configured to store information in distinct magnetization states. It can generate a stray magnetic field corresponding to the magnetization state of the stored information. The cell can include a magnetic field detection device positioned in proximity to the magnetic memory element, which can detect variations in the stray magnetic field from the magnetic layer. The detection device can comprise or consist of a magnetostrictive and piezoelectric layer assembly, or a piezomagnetic and piezoelectric layer assembly. The magnetostrictive or piezomagnetic layer can be configured to undergo a mechanical deformation in response to a change in the stray magnetic field. The piezoelectric layer can be configured to generate an electrical signal based on the mechanical deformation, the electrical signal representing the information stored in the magnetic memory element. The cell can further include a writing mechanism configured to alter the magnetization state of the magnetic layer.

It is an advantage of some embodiments of the disclosed technology that the magnetic field detection device, using a combination of magnetostrictive or piezomagnetic and piezoelectric layers, can provide a more sensitive readout than other magnetoresistive-based detection. By responding directly to variations in stray magnetic fields, this setup can enable higher sensitivity to magnetization states, allowing for more reliable detection, even at lower magnetic signal strengths.

In embodiments of the disclosed technology, the at least one magnetic layer can have a perpendicular magnetic anisotropy.

It is an advantage of some embodiments of the disclosed technology that a perpendicular magnetic anisotropy can be more advantageous for downscaling.

In embodiments of the disclosed technology, the magnetic memory element can comprise a plurality of magnetic layers, separated by non-magnetic spacer layers (for example, non-magnetic spacer layers alternating with magnetic layers). These magnetic layers can be designed to store information in distinct magnetization states. The arrangement of the magnetic layers can help ensure that their stray fields, generated above the memory stack, either combine additively or partially compensate for one another. In embodiments of the disclosed technology, each magnetic layer can have perpendicular magnetic anisotropy.

It is an advantage of some embodiments of the disclosed technology that the increased sensitivity readout design can allow for multilayer configurations in the magnetic memory element. The multilayer option can enable additional data density, as each layer can hold distinct magnetization states. The design's high sensitivity can support accurate readout of multilayer configurations, making it suitable for multibit storage.

In embodiments of the disclosed technology, a cumulative stray field can be created with distinct levels corresponding to different magnetization configurations of the magnetic layers.

In embodiments of the disclosed technology, the writing mechanism can be configured to individually alter the magnetization state of the one or more magnetic layers.

In embodiments of the disclosed technology, the magnetic field detection device can comprise a thin-film transistor (TFT). A gate of the thin-film transistor can be connected with a terminal of the piezoelectric layer such that a voltage over the piezoelectric layer controls the gate-source voltage of the thin-film transistor.

It is an advantage of some embodiments of the disclosed technology that the thin-film transistor can serve as an active amplification component, allowing small variations in the voltage generated by the piezoelectric layer in response to changes in the stray magnetic field to control a larger current through the transistor.

It is, moreover, an advantage of some embodiments of the disclosed technology that by integrating a thin-film transistor directly with the piezoelectric layer the need for complex sense amplifier circuitry can be eliminated. The simpler and more compact thin-film transistor design allows for a smaller footprint, making it well-suited for high-density applications and reducing overall circuit complexity.

In embodiments, the magnetic field detection device can comprise a sense amplifier configured to amplify a voltage over the piezoelectric layer.

It is an advantage of some embodiments of the disclosed technology that the sense amplifier can amplify the voltage generated by the piezoelectric layer thus increasing the sensitivity to changes in the stray magnetic field and therefore to changes in the magnetization states.

In embodiments of the disclosed technology, the writing mechanism can comprise two terminals at outer ends of magnetic memory element configured to alter the magnetization state of the one or more magnetic layers.

It is an advantage of some embodiments of the disclosed technology that the placement of terminals at opposite ends of the memory element can allow for efficient current flow across the magnetic layers, which can be optimal for achieving the required spin-transfer torque (STT) or other current-based writing mechanisms.

In embodiments of the disclosed technology, the magnetic memory element can comprise at least one polarizing layer.

In embodiments of the disclosed technology, the writing mechanism can be configured to individually alter the magnetization state of the one or more magnetic layers by applying spin-transfer torque or voltage-controlled magnetic anisotropy or a combination of spin-transfer torque or voltage-controlled magnetic anisotropy.

In embodiments of the disclosed technology, the magnetic field detection device can comprise the magnetostrictive and the piezoelectric layer and the magnetostrictive layer can include a layer with in-plane anisotropy.

In embodiments of the disclosed technology, magnetic layers of the magnetic memory element can be arranged such that their respective stray fields at the location of the magnetic field detection device stack are additive or partially compensating.

It is an advantage of some embodiments of the disclosed technology that a cumulative stray field with distinct levels corresponding to different magnetization configurations of the magnetic layers can be created.

In embodiments of the disclosed technology, the magnetic memory cell can comprise a control circuit configured to adjust the voltage across the one or more magnetic layers for altering the magnetization state of the one or more magnetic layers.

In a second aspect, embodiments of the disclosed technology relate to a method of operating a magnetic memory cell. The method can comprise:
applying a control signal to a writing mechanism configured to alter the magnetization state of at least one magnetic layer within a magnetic memory element of the memory cell, wherein the magnetization state corresponds to the information to be stored,
detecting variations in the stray magnetic field generated by the at least one magnetic layer using a magnetic field detection device comprising a magnetostrictive and piezoelectric or piezomagnetic and piezoelectric layer assembly, and
generating an electrical signal in response to the detected stray magnetic field via the piezoelectric layer, wherein the electrical signal represents the information stored in the magnetic memory element.

In embodiments of the disclosed technology, the control signal can be applied to alter the magnetization state of multiple magnetic layers within the magnetic memory element, each separated by a non-magnetic spacer (e.g., adjacent ones of the multiple magnetic layers are separated by a non-magnetic spacer), resulting in distinct stray field levels based on the collective magnetization states of the magnetic layers, and wherein the distinct stray fields can be detected by detecting the variations in the stray magnetic field to determine multi-bit information stored in the magnetic memory cell.

In embodiments of the disclosed technology, detecting the variations in the stray magnetic field can comprise:
inducing mechanical deformation in the magnetostrictive or piezomagnetic layer of the magnetic field detection device due to the stray field,
converting the mechanical deformation into a voltage signal using the piezoelectric layer, and
amplifying the voltage signal with a sense amplifier or using the voltage signal to control a gate of a thin-film transistor.

In embodiments of the disclosed technology, the method can comprise:
configuring the writing mechanism to alter the magnetization state of the one or more magnetic layers by applying spin-transfer torque, voltage-controlled magnetic anisotropy (VCMA), or a combination of STT and VCMA, and
selectively adjusting the control signal to individually alter the magnetization states of the magnetic layers, enabling multi-level storage and retrieval of data in the magnetic memory cell.

Particular and preferred aspects of the disclosed technology are set out in the accompanying independent and dependent claims. Features from the dependent claims may be combined with features of the independent claims and with features of other dependent claims as appropriate and not merely as explicitly set out in the claims.

These and other aspects of the disclosed technology will be apparent from and elucidated with reference to the embodiment(s) described hereinafter.

### BRIEF DESCRIPTION OF THE DRAWINGS

FIG. 1 shows a schematic drawing of an example stack of a single-bit magnetic memory cell with magnetoelectric reading in accordance with embodiments of the disclosed technology.

FIG. 2 shows a schematic drawing of an example stack of a multi-bit magnetic memory cell with magnetoelectric reading in accordance with embodiments of the disclosed technology.

FIG. 3 shows a schematic drawing of an example stack of a single-bit magnetic memory cell with magnetoelectric reading with transistor integration in accordance with embodiments of the disclosed technology.

FIG. 4 shows a schematic drawing of an example stack of a multi-bit magnetic memory cell with magnetoelectric reading with transistor integration in accordance with embodiments of the disclosed technology.

FIG. 5 shows the stray magnetic field of an example memory cell that varies in discrete steps as different magnetic layers are switched up or down in accordance with embodiments of the disclosed technology.

FIG. 6 shows a flow chart of an example method in accordance with embodiments of the disclosed technology.

Any reference signs in the claims shall not be construed as limiting the scope.

In the different drawings, the same reference signs can refer to the same or analogous elements.

### DETAILED DESCRIPTION OF CERTAIN ILLUSTRATIVE EMBODIMENTS

The disclosed technology will be described with respect to particular embodiments and with reference to certain drawings but the disclosed technology is not limited thereto but only by the claims. The drawings described are only schematic and are non-limiting. In the drawings, the size of some of the elements may be exaggerated and not drawn on scale for illustrative purposes. The dimensions and the relative dimensions do not correspond to actual reductions to practice of the disclosed technology.

The terms first, second and the like in the description and in the claims, are used for distinguishing between similar elements and not necessarily for describing a sequence, either temporally, spatially, in ranking or in any other manner. It is to be understood that the terms so used are interchangeable under appropriate circumstances and that the embodiments of the disclosed technology described herein are capable of operation in other sequences than described or illustrated herein.

Moreover, the terms top, under and the like in the description and the claims are used for descriptive purposes and not necessarily for describing relative positions. It is to be understood that the terms so used are interchangeable under appropriate circumstances and that the embodiments of the disclosed technology described herein are capable of operation in other orientations than described or illustrated herein.

It is to be noticed that the term “comprising”, used in the claims, should not be interpreted as being restricted to the means listed thereafter; it does not exclude other elements or steps. It is thus to be interpreted as specifying the presence of the stated features, integers, steps or components as referred to, but does not preclude the presence or addition of one or more other features, integers, steps or components, or groups thereof. Thus, the scope of the expression “a device comprising means A and B” should not be limited to devices consisting only of components A and B. It means that with respect to the disclosed technology, the only relevant components of the device are A and B.

Reference throughout this specification to “one embodiment” or “an embodiment” means that a particular feature, structure or characteristic described in connection with the embodiment is included in at least one embodiment of the disclosed technology. Thus, appearances of the phrases “in one embodiment” or “in an embodiment” in various places throughout this specification are not necessarily all referring to the same embodiment, but may. Furthermore, the particular features, structures or characteristics may be combined in any suitable manner, as would be apparent to one of ordinary skill in the art from this disclosure, in one or more embodiments.

Similarly it should be appreciated that in the description of exemplary embodiments of the disclosed technology, various features of the disclosed technology are sometimes grouped together in a single embodiment, figure, or description thereof for the purpose of streamlining the disclosure and aiding in the understanding of one or more of the various inventive aspects. This method of disclosure, however, is not to be interpreted as reflecting an intention that the claimed invention requires more features than are expressly recited in each claim. Rather, as the following claims reflect, inventive aspects lie in less than all features of a single foregoing disclosed embodiment. Thus, the claims following the detailed description are hereby expressly incorporated into this detailed description, with each claim standing on its own as a separate embodiment of disclosed technology.

Furthermore, while some embodiments described herein include some but not other features included in other embodiments, combinations of features of different embodiments are meant to be within the scope of the disclosed technology, and form different embodiments, as would be understood by those in the art. For example, in the following claims, any of the claimed embodiments can be used in any combination.

In the description provided herein, numerous specific details are set forth. However, it is understood that embodiments of the disclosed technology may be practiced without these specific details. In other instances, well-known methods, structures and techniques have not been shown in detail in order not to obscure an understanding of this description.

Where in embodiments of the disclosed technology reference is made to a magnetic field detection device which is arranged in proximity to the magnetic memory element, reference is made to a field detection device which is arranged close enough to the magnetic memory element for detecting the stray fields using a magnetostrictive and a piezoelectric or a piezomagnetic and a piezoelectric layer assembly. It is thereby noted that the stray field can decrease with the distance (for example, proportional with 1/d³).

The disclosed technology relates to a magnetic memory cell that can enable efficient storage and retrieval of information by employing a novel architecture that supports multi-bit storage within a single device. A scheme is proposed where several magnetic layers, forming a memory stack, can be used to store more than one bit of information. This is achieved by designing the memory element to generate stray magnetic fields that correspond to distinct magnetization states of the individual magnetic layers, allowing for multilevel information representation.

The reading mechanism can be based on the generation of charge or voltage through the inverse magnetoelectric effect in magnetostrictive/piezoelectric or piezomagnetic/piezoelectric composites. This approach can utilize a magnetic field detection device positioned in proximity to the memory stack, which detects variations in the stray magnetic field. The detection device can convert these magnetic field variations into electrical signals through the mechanical deformation of the magnetostrictive or piezomagnetic layer, coupled with the piezoelectric layer. This mechanism can offer the potential for reduced energy consumption during the readout process compared to other methods.

The magnetic memory cell can further comprise a writing mechanism designed to alter the magnetization state of the magnetic layers. This can enable precise control over the stored information, facilitating the implementation of high-density, energy-efficient memory devices. The disclosed technology provides a significant step forward in magnetic memory technologies, addressing limitations of other architectures and enabling new applications in data storage and processing.

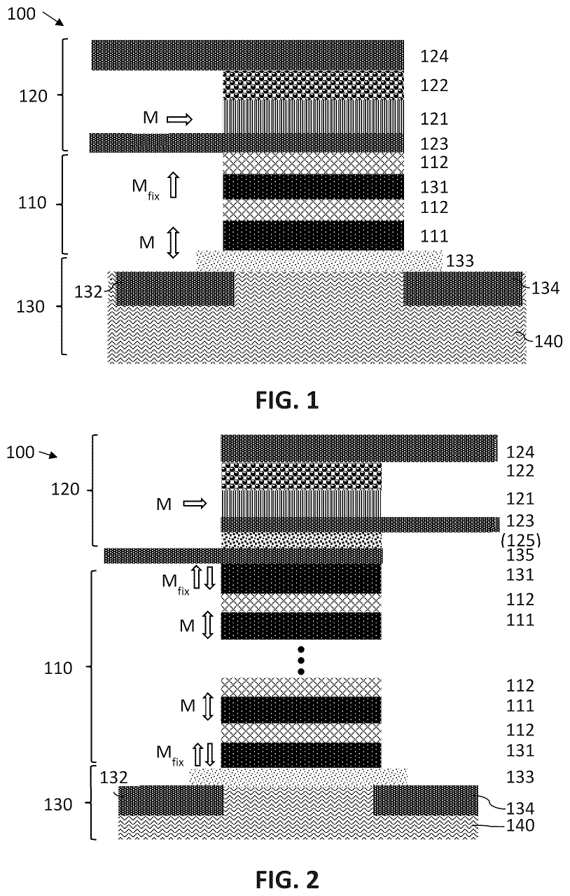

In a first aspect, embodiments of the disclosed technology relate to a magnetic memory cell (100) comprising a magnetic memory element (110), a magnetic field detection device (120), and a writing mechanism (130). Example stacks of such a device are shown in FIG. 1 to FIG. 4. In FIG. 1 to FIG. 4, the stacks of the magnetic memory cells are built on a substrate (140)

The magnetic memory element (110) can include at least one magnetic layer (111) configured to store information in distinct magnetization states. These magnetization states generate a stray magnetic field corresponding to the stored information. The magnetic layer may exhibit perpendicular magnetic anisotropy.

In embodiments of a magnetostrictive layer, the magnetization of the magnetostrictive layer, which exhibits in-plane anisotropy, can rotate in response to the stray fields from the memory stack. This rotation can induce mechanical stress in the magnetostrictive layer, which can be transferred to the piezoelectric layer. The stress in the piezoelectric layer can generate a charge separation and an electrical voltage that can be measured across a pair of electrodes (123), (124) (see the example embodiments of FIG. 1 to FIG. 4). This voltage can correspond to the magnetization state and can allow for precise determination of the memory level.

In embodiments of a piezomagnetic layer, the up or down orientation of the magnetization in the piezomagnetic layer can generate stress, which can be transferred to the piezoelectric layer, resulting in voltage generation. This approach can further expand the number of distinguishable memory levels by leveraging the unique responses of the piezomagnetic/piezoelectric composites to varying stray field strengths.

The magnetic field detection device (120) can be arranged in proximity to the magnetic memory element (110) to detect variations in the stray magnetic field. The detection device can comprise a magnetostrictive (121) and piezoelectric (122) layer assembly or, alternatively, a piezomagnetic (121) and piezoelectric (122) layer assembly. Changes in the stray magnetic field can induce mechanical deformation in the magnetostrictive or piezomagnetic layer, which can be converted into an electrical signal by the piezoelectric layer. This electrical signal can represent the information stored in the magnetic memory element and can facilitate the readout process.

Embodiments of the disclosed technology may extend to multi-bit storage within a single magnetic memory cell. This is achieved by utilizing multiple magnetic layers (111) within the magnetic memory element (110), separated by non-magnetic spacer layers. Each magnetic layer can store information in distinct magnetization states, and their respective stray magnetic fields can interact additively or partially compensate to create discrete field levels detectable by the magnetic field detection device (120). Such a configuration can enable the storage of multiple bits of information in a single memory device, as illustrated in FIG. 2 and FIG. 4.

The writing mechanism (130) can be configured to alter the magnetization state of the one or more magnetic layers (111), enabling the writing or updating of information within the memory cell. This mechanism can utilize a two-terminal configuration based on spin-transfer torque (STT), employing one or multiple fixed magnetic layers as polarizers with different magnetic orientations. Alternatively, the writing process may involve voltage-controlled magnetic anisotropy (VCMA) or a combination of STT and VCMA, depending on the specific memory cell configuration.

In embodiments of the disclosed technology, the writing mechanism (130) can comprise two terminals at outer ends of the magnetic memory element (110) configured to alter the magnetization state of the one or more magnetic layers (111).

Two terminals (132, 134) may be present at outer ends of a spin-orbit torque (SOT) track (133). In embodiments of the disclosed technology with reference made to an SOT track, reference can be made to a conductive layer composed of a material with strong spin-orbit coupling properties, such as a heavy metal, topological insulator, or similar material. This layer can be configured to generate a spin current via the spin Hall effect or Rashba effect when a charge current is applied, and this spin current can be used to exert a torque on the magnetization of an adjacent magnetic layer to alter its state. Examples thereof are shown in FIG. 1 to FIG. 4.

More advanced writing schemes, such as those combining STT with SOT or voltage-gated SOT (VG-SOT), are also possible. However, these architectures can generally use additional electrical terminals, increasing complexity.

In embodiments of the disclosed technology, the writing mechanism can be similar to those used in magnetic tunnel junction MRAM technologies, with spatial density being influenced by the coupling or magnetic field interactions with neighboring devices. This can help ensure compatibility with existing fabrication processes while maintaining the scalability and functionality of the memory cell.

In embodiments of the disclosed technology, the magnetic memory element can comprise at least one polarizing layer (131). It is an advantage of some embodiments of the disclosed technology that when an electric current flows through the polarizing layer, a stream of electrons with spins aligned in a specific direction can be obtained. This can allow the use of STT as a writing mechanism configured to alter the magnetization state of the at least one magnetic layer.

In embodiments of the disclosed technology, such as illustrated in FIG. 1 to FIG. 4, terminals (132) and (134) can be positioned at the outer ends of an SOT track, allowing a charge current to flow through the track.

In embodiments of the disclosed technology, a polarizing layer (131) may be positioned adjacent to the SOT track, which can serve to polarize the spin current. This polarizing layer can be a fixed magnetic layer with a stable magnetization direction, helping ensure that the spin current generated by the SOT track can be effectively polarized before interacting with the magnetic memory element.

In embodiments of the disclosed technology, the magnetic layers may be written by flowing a current through the stack. This current may, for example, be applied between electrodes at outer ends of the stack (for example, electrode (123) at one end of the stack and electrode (132) or (134) at the opposite end of the stack). In this embodiment, the writing mechanism can be based on STT and polarizer layers (131) can be utilized. More than one polarizing layer (131) may be applied to allow for more combinations/bits. In some such embodiments, the SOT track (133) may not be needed and only a single bottom electrode (132 or 134) can be used.

In embodiments of the disclosed technology, layers of the memory element may be written using STT and a top polarizing layer. In some such embodiments, a bottom polarizing layer (131) may not be required. In such embodiments, layers of the memory element can be written using STT and the top polarizer, whereas the SOT track can write the bottom magnetic layer as in FIG. 1. For such embodiments, a stack as shown in FIG. 2 can be modified such that the bottom magnetic layer (111) can be positioned directly on top of the SOT track (133).

An example of a writing mechanism (130) with three terminals is illustrated in FIG. 2 and FIG. 4. The writing mechanism may utilize STT, VCMA, or SOT to alter the magnetization state of the magnetic layers within the magnetic memory element. The writing process can involve the application of electrical signals through specific terminals configured for these mechanisms.

Adjacent to the polarizing layer (131) can include a non-magnetic spacer layer (112). This layer can decouple the polarizing layer from the adjacent magnetic layer, preventing direct magnetic coupling while allowing the spin-polarized current to transfer efficiently through the stack.

Adjacent to the non-magnetic spacer layer (112) can include the magnetic layer (111), which can serve as the storage element of the memory cell. The magnetization state of this layer can be altered by the spin current generated by the SOT track and polarized by the polarizing layer. This configuration can allow precise control of the magnetization state of the magnetic layer, enabling reliable writing operations.

The stack illustrated in FIG. 2 and FIG. 4 can comprise a plurality of stacked non-magnetic spacer layers (112) and magnetic layers (111), arranged alternately to form a multilayer structure. Each magnetic layer (111) can be separated by a non-magnetic spacer layer (112), which can prevent direct magnetic coupling between adjacent magnetic layers while enabling efficient interaction via stray fields or spin-polarized currents.

On top of the stack, a second polarizing layer (131) can be provided. This layer can function as an additional fixed magnetic layer with a stable magnetization direction, complementing the first polarizing layer (131) positioned adjacent to the SOT track at the base of the stack. The second polarizing layer can enhance the control over spin polarization and stray field interactions, contributing to improved readout accuracy and multi-bit storage capability.

In addition to terminals (132) and (134), a terminal (135) can be positioned on the opposite side of the magnetic memory element compared to terminals (132) and (134). This terminal can facilitate the application of a voltage or current for mechanisms like STT or VCMA, providing another control point to alter the magnetization state of the magnetic layers.

A polarizing layer may not be strictly required. It may, for example, not be required in the embodiments of one single layer and a spin-orbit torque as a writing mechanism. In a spin-orbit torque-based memory cell, a heavy metal layer can be placed adjacent to the magnetic storage layer. When a charge current is passed through the heavy metal layer, the spin Hall effect can generate a transverse spin current (for example, perpendicular to the charge current). This spin current can accumulate at the interface with the magnetic layer, producing a torque on its magnetization. This torque can switch the magnetization direction (for example, up or down) depending on the polarity and magnitude of the applied current. This switching can represent the data being written (for example, a binary 0 or 1).

In embodiments of the disclosed technology, the magnetic memory element (110) and the magnetic field detection device (120) can be arranged in a vertical arrangement to optimize the compactness and efficiency of the memory cell (100) design. In this configuration, the magnetic memory element (110), comprising one or more magnetic layers (111) separated by non-magnetic spacer layers (112), can be positioned directly beneath the magnetic field detection device (120).

This vertical stacking can enable the stray magnetic fields generated by the magnetic memory element (110) to propagate upwards directly to the magnetic field detection device (120) without significant loss of field strength. The proximity between the components can help ensure in various embodiments, that the detection device (120), which can include a magnetostrictive (121) and piezoelectric (122) or piezomagnetic (121) and piezoelectric (122) layer assembly, can accurately and efficiently detect variations in the stray magnetic field corresponding to the magnetization states of the memory layers (111).

The vertical arrangement can also facilitate efficient integration of the memory cell (100) into larger arrays, as it can reduce and/or minimize the lateral footprint of each cell. This design can be particularly advantageous for high-density memory applications, where space optimization can be critical. Moreover, the vertical arrangement can allow for precise alignment of the detection device (120) with the memory element (110), enhancing the reliability of the readout process while reducing energy consumption and signal interference.

The spacer layers (112) used in the magnetic memory element (110) of the disclosed technology may comprise non-magnetic metals or oxides.

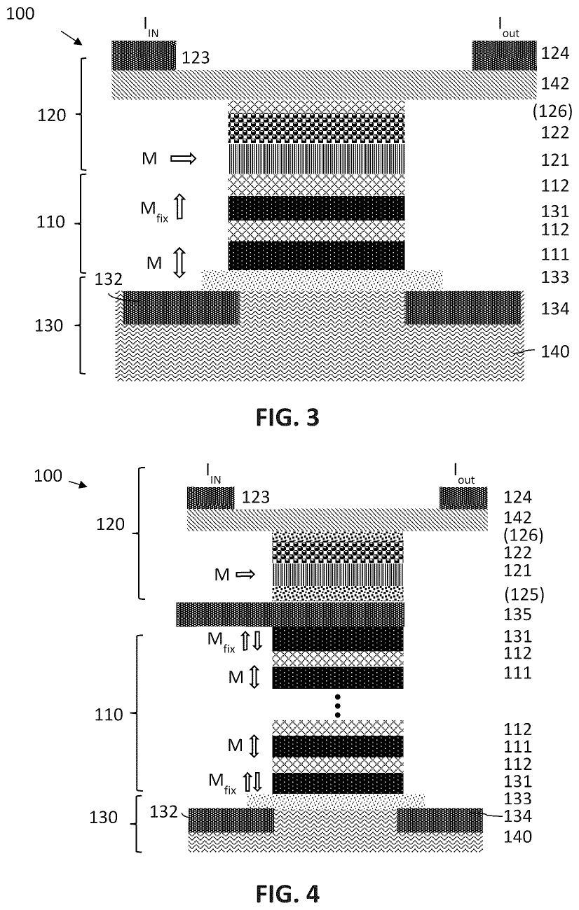

In embodiments of the disclosed technology, such as illustrated in FIG. 3 and FIG. 4, a thin-film transistor (142) can be integrated into the magnetic field detection device (120) to enhance readout functionality. The thin-film transistor (142) can provide signal amplification and can facilitate efficient electrical interfacing with external circuitry.

The gate of the thin-film transistor (142) can be electrically connected to a terminal of the piezoelectric layer (122). This connection can enable the voltage generated across the piezoelectric layer (122) in response to mechanical deformation to control the gate-source voltage of the thin-film transistor (142). This configuration can help ensure accurate signal transfer from the detection device to the output circuitry.

Contacts Iᵢₙ (123) and Iₒᵤₜ (124) can be provided to interface with the input and output terminals of the thin-film transistor (142), allowing the amplified electrical signal to be processed further.

Optionally, in the embodiment illustrated in FIG. 2, an insulator (125) may be positioned between the memory element (110) and the detection device (120) configured to electrically decouple the writing part (for example, voltages-currents applied to write the memory element) and the reading voltage for the output between the pair of electrodes (123, 124).

Optionally, in the embodiment illustrated in FIG. 4, the insulator (125) may be positioned between the magnetostrictive or piezomagnetic layer (121) and a terminal (135) of the writing mechanism (130).

Optionally, in the embodiments illustrated in FIG. 3 and FIG. 4, an insulator (126) may be positioned between the thin-film transistor (142) and the piezoelectric layer (122). This insulator layer (126) may not change the accumulated charge at the piezoelectric layer (122) but may be advantageous for the integration of the different layers and for reducing leakage.

The integration of the TFT within the detection device (120) can add several advantages in various embodiments. In various embodiments, it can simplify signal amplification by embedding it directly in the memory cell structure, reducing the need for external amplifiers. Furthermore, as seen in FIG. 3, this configuration can be particularly effective for single-bit readout applications, while FIG. 4 demonstrates its scalability and utility in multi-bit memory cells, where the detection device (120) can read varying stray field levels from multiple magnetic layers (111) within the memory element (110).

This arrangement can help ensure a compact and energy-efficient design, as the direct connection between the piezoelectric layer (122) and the TFT minimizes signal loss and interference. Additionally, the TFT integration can facilitate seamless compatibility with modern semiconductor fabrication processes, making it highly suitable for high-density memory applications.

In embodiments of the disclosed technology, the magnetic field detection device (120) may comprise a sense amplifier configured to amplify a voltage over the piezoelectric layer (122).

The overall magnetic memory stack can generate a magnetic stray field, the magnitude of which can be determined by the relative orientation (for example, up or down) of the magnetization in the individual memory layers. As each magnetic layer switches its magnetization state, the stray field can change in discrete steps, providing a distinct signal for each configuration of the memory layers. This stepwise variation in the stray field can be a key feature of the multilevel memory cell, allowing it to store multiple bits of information.

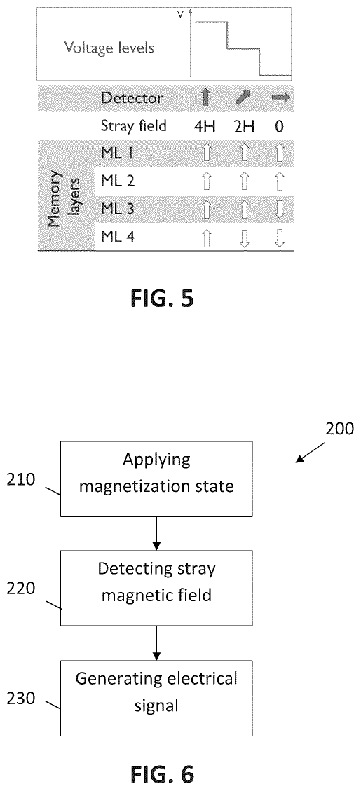

It is noteworthy that the memory layers can be designed such that their stray fields either fully or partially compensate each other at the position of the magnetic field detection device. This design flexibility can enable precise control over the stray field strength, improving the readout accuracy and efficiency of the detection device while reducing and/or minimizing interference from unwanted magnetic field components. FIG. 5 illustrates the magnetic stray field produced by the overall magnetic memory stack, showing how the stray field can vary in discrete steps as the magnetization states of the individual memory layers are switched up or down. The diagram demonstrates the stepwise nature of the stray field changes and highlights the potential for full or partial compensation of the stray fields at the detector position, depending on the relative orientation of the magnetization in the memory layers.

In embodiments of the disclosed technology, the magnetic memory cell (100) can include a control circuit designed to manage the voltage applied between terminals at outer ends of a magnetic memory element (110). This may be between terminals (132, 134) at outer ends of an SOT track (133) or between terminals (135, 132 or 134) at opposite ends of the stack of layers of the magnetic memory element (110). This control circuit can facilitate the adjustment of the magnetization state of the magnetic layers, enabling reliable write operations within the memory cell. Such a control circuit may for example comprise a voltage controlled current source, or a digital-to-analog converter.

In a second aspect, embodiments of the disclosed technology relate to a method (200) of operating a magnetic memory cell (100) in accordance with embodiments of the disclosed technology. The method (200) can comprise multiple steps to write, detect, and read stored information. This method can help ensure efficient and accurate operation of the magnetic memory cell by leveraging advanced writing and detection mechanisms.

In a first step, a control signal can be applied (210) to a writing mechanism (130) that is configured to alter the magnetization state of at least one magnetic layer (111) within the magnetic memory element (110). The magnetization state can correspond to the information to be stored, allowing precise and reliable data encoding in the memory cell.

The next step can involve detecting variations (220) in the stray magnetic field generated by the magnetization state of the at least one magnetic layer (111). This detection can be performed using a magnetic field detection device (120) comprising a magnetostrictive (121) and piezoelectric (122) layer assembly or, alternatively, a piezomagnetic (121) and piezoelectric (122) layer assembly. The detection process can capture the changes in the stray field corresponding to the stored information.

Following detection, an electrical signal can be generated (230) in response to the detected stray magnetic field. This signal can be produced by the piezoelectric layer (122) and can represent the information stored in the magnetic memory element (110). The generated signal can serve as the basis for reading the stored data.

In embodiments of the disclosed technology, the method can involve applying the control signal (210) to alter the magnetization states of multiple magnetic layers (111) within the magnetic memory element (110). These layers can be separated by nonmagnetic spacer layers (112) and configured to collectively generate distinct stray field levels. By detecting (220) the variations in the stray magnetic field, the method can enable the determination of multi-bit information stored in the memory cell (100).

In embodiments of the disclosed technology, detecting variations in the stray magnetic field (220) can comprise inducing mechanical deformation in the magnetostrictive (121) or piezomagnetic (121) layer of the magnetic field detection device (120) due to the stray field. This mechanical deformation can then be converted into a voltage signal using the piezoelectric layer (122). The resulting voltage signal may be amplified using a sense amplifier or used to control the gate of a thin-film transistor (142), helping ensure accurate and efficient data readout.

In embodiments of the disclosed technology, the method can comprise configuring the writing mechanism (130) to alter the magnetization states of one or more magnetic layers (111) using STT, VCMA, or a combination of these mechanisms. The control signal can be selectively adjusted to individually alter the magnetization states of the magnetic layers, enabling multi-level storage of data within the magnetic memory cell (100). Multi-level retrieval of data within the magnetic memory cell can be enabled by detecting (220) the variations in the stray magnetic field using a magnetic field detection device (120) comprising a magnetostrictive (121) and piezoelectric (122) or piezomagnetic (121) and piezoelectric (122) layer assembly. This selective control and detection can help ensure flexible and scalable operation, making the memory cell suitable for high-density storage applications.

The stack in FIG. 1, showing single-bit SOT in combination with reading using a magnet field detection device in accordance with embodiments of the disclosed technology, comprises the following layers from top to bottom:
124: Electrode for detection device.
122: Piezoelectric layer for voltage generation.
121: Magnetostrictive or piezomagnetic layer that deforms in response to stray magnetic fields.
123: Electrode for the detection device.
112: Non-magnetic spacer layer.
131: Polarizing layer to polarize the spin current.
112: Non-magnetic spacer layer.
111: Magnetic layer configured to store information.
133: SOT track configured to generate spin currents.
132, 134: Terminals configured to apply current through the SOT track for writing mechanism.
140: Substrate providing mechanical support and integration.

The stack in FIG. 2, showing multibit SOT in combination with reading using a magnetic field detection device in accordance with embodiments of the disclosed technology, comprises the following layers from top to bottom:
124: Electrode for detection device.
122: Piezoelectric layer for voltage generation.
121: Magnetostrictive or piezomagnetic layer that deforms in response to stray magnetic fields.
123: Electrode for the detection device.
125: Optional insulator.
135: Terminal for writing mechanism.
131: Polarizing layer to polarize the spin current.
112: Non-magnetic spacer layer.
111: Magnetic layer configured to store information.
Additional alternating layers of non-magnetic spacer layers (112) and magnetic layers (111).
131: Polarizing layer at the bottom of the stack.
133: SOT track configured to generate spin currents.
132, 134: Terminals configured to apply current through the SOT track for writing mechanism.
140: Substrate providing mechanical support and integration.

The stack in FIG. 3, showing single-bit SOT in combination with reading using a thin-film transistor and magnetic field detection device in accordance with embodiments of the disclosed technology, comprises the following layers from top to bottom:
123: Electrode for the detection device.
124: Electrode for detection device.
142: Thin-film transistor for signal amplification.
126: Optional insulator.
122: Piezoelectric layer for voltage generation.
121: Magnetostrictive or piezomagnetic layer that deforms in response to stray magnetic fields.
112: Non-magnetic spacer layer.
131: Polarizing layer to polarize the spin current.
112: Non-magnetic spacer layer.
111: Magnetic layer configured to store information.
133: SOT track configured to generate spin currents.
132, 134: Terminals configured to apply current through the SOT track for writing mechanism.
140: Substrate providing mechanical support and integration.

The stack in FIG. 4, showing multibit SOT in combination with reading using a thin-film transistor and magnetic field detection device in accordance with embodiments of the disclosed technology, comprises the following layers from top to bottom:
123: Electrode for the detection device.
124: Electrode for the detection device.
142: Thin-film transistor for signal amplification.
126: Optional insulator.
122: Piezoelectric layer for voltage generation.
121: Magnetostrictive or piezomagnetic layer that deforms in response to stray magnetic fields.
125: Optional insulator.
135: Terminal for writing mechanism.
131: Polarizing layer to polarize the spin current.
112: Non-magnetic spacer layer.
111: Magnetic layer configured to store information.
Additional alternating layers of non-magnetic spacer layers (112) and magnetic layers (111).
131: Polarizing layer at the bottom of the stack.
133: SOT track configured to generate spin currents.
132, 134: Terminals configured to apply current through the SOT track for writing mechanism.
140: Substrate providing mechanical support and integration.

What is claimed is:

1. A magnetic memory cell comprising:
a magnetic memory element with at least one magnetic layer configured to store information in distinct magnetization states, the at least one magnetic layer generating a stray magnetic field corresponding to the magnetization state of the stored information;
a magnetic field detection device positioned in proximity to the magnetic memory element and configured to detect variations in the stray magnetic field from the magnetic memory element, the magnetic field detection device comprising a layer assembly comprising: (1) a magnetostrictive layer and a piezoelectric layer or (2) a piezomagnetic layer and a piezoelectric layer, wherein the magnetostrictive layer or the piezomagnetic layer is configured to undergo a mechanical deformation in response to a change in the stray magnetic field, and the piezoelectric layer is configured to generate an electrical signal based on the mechanical deformation, the electrical signal representing the information stored in the magnetic memory element; and
a writing mechanism configured to alter the magnetization state of the at least one magnetic layer.

2. The magnetic memory cell according to claim 1, wherein the at least one magnetic layer has a perpendicular magnetic anisotropy.

3. The magnetic memory cell according to claim 1, wherein the at least one magnetic layer comprises a plurality of magnetic layers forming a memory stack, each magnetic layer configured to store information in distinct magnetization states.

4. The magnetic memory cell according to claim 3, wherein the magnetic memory element further comprises non-magnetic spacer layers alternating with the magnetic layers.

5. The magnetic memory cell according to claim 3, wherein the magnetic layers are arranged such that respective stray magnetic fields of the magnetic layers above the memory stack are additive or partially compensating.

6. The magnetic memory cell according to claim 1, wherein the magnetic field detection device comprises a thin-film transistor, wherein a gate of the thin-film transistor is connected with a terminal of the piezoelectric layer such that a voltage over the piezoelectric layer controls a gate-source voltage of the thin-film transistor.

7. The magnetic memory cell according to claim 1, wherein the magnetic field detection device comprises a sense amplifier configured to amplify a voltage over the piezoelectric layer.

8. The magnetic memory cell according to claim 1, wherein the writing mechanism comprises two terminals at outer ends of the magnetic memory element configured to alter the magnetization state of the at least one magnetic layer.

9. The magnetic memory cell according to claim 1, wherein the magnetic memory element comprises at least one polarizing layer.

10. The magnetic memory cell according to claim 1, wherein the writing mechanism is configured to individually alter the magnetization state of the at least one magnetic layer by applying a spin-transfer torque or a voltage-controlled magnetic anisotropy or a combination of the spin-transfer torque and the voltage-controlled magnetic anisotropy.

11. The magnetic memory cell according to claim 1, wherein the magnetic field detection device comprises the magnetostrictive and the piezoelectric layer and wherein the magnetostrictive layer comprises a layer with an in-plane anisotropy.

12. The magnetic memory cell according to claim 1, wherein the at least one magnetic layer comprises a plurality of magnetic layers arranged such that the respective stray magnetic fields at the location of the magnetic field detection device are additive or partially compensating.

13. The magnetic memory cell according to claim 1, further comprising a control circuit configured to adjust a voltage across the at least one magnetic layer to alter the magnetization state of the at least one magnetic layer.

14. A method of operating a magnetic memory cell, the method comprising:
applying a control signal to a writing mechanism configured to alter a magnetization state of at least one magnetic layer within a magnetic memory element of the memory cell, wherein the magnetization state corresponds to information to be stored;
detecting variations in a stray magnetic field generated by the at least one magnetic layer using a magnetic field detection device comprising a layer assembly, the layer assembly comprising (1) a magnetostrictive layer and a piezoelectric layer or (2) a piezomagnetic layer and a piezoelectric layer; and
generating an electrical signal in response to the detected stray magnetic field via the piezoelectric layer, wherein the electrical signal represents the information stored in the magnetic memory element.

15. The method according to claim 14, wherein the control signal is applied to alter the magnetization state of multiple magnetic layers of the at least one magnetic layer within the magnetic memory element, wherein adjacent ones of the multiple magnetic layers are separated by a non-magnetic spacer, resulting in distinct stray field levels based on the collective magnetization states of the multiple magnetic layers

16. The method according to claim 15, wherein the distinct stray field levels are detected by detecting variations in the stray magnetic field to determine multi-bit information stored in the magnetic memory cell.

17. The method according to claim 14, wherein detecting the variations in the stray magnetic field comprises:
inducing a mechanical deformation in the magnetostrictive layer or the piezomagnetic layer of the magnetic field detection device due to the stray magnetic field;
converting the mechanical deformation into a voltage signal using the piezoelectric layer; and
amplifying the voltage signal with a sense amplifier or using the voltage signal to control a gate of a thin-film transistor.

18. The method according to claim 14, further comprising configuring the writing mechanism to alter the magnetization state of the at least one magnetic layer by applying a spin-transfer torque (STT), a voltage-controlled magnetic anisotropy (VCMA), or a combination of the STT and the VCMA.

19. The method according to claim 14, further comprising selectively adjusting the control signal to individually alter the magnetization state of the at least one magnetic layer, enabling multi-level storage and retrieval of data in the magnetic memory cell.
